(19) United States
(12) Patent Application Publication
(10) Pub. No.: US 2025/0008762 A1
(43) Pub. Date: Jan. 2, 2025

(54) LIGHT EMITTING ELEMENT, DISPLAY DEVICE, AND ELECTRONIC DEVICE

(71) Applicant: Sony Semiconductor Solutions Corporation, Kanagawa (JP)

(72) Inventor: Masaaki Sekine, Saitama (JP)

(21) Appl. No.: 18/703,922

(22) PCT Filed: Nov. 18, 2022
(86) PCT No.: PCT/JP22/42869

§ 371 Date: Apr. 23, 2024

(30) Foreign Application Priority Data
Nov. 29, 2021 (JP) 2021-193296

(51) Int. Cl. H10K 50/125; H10K 50/813

(52) U.S. Cl. CPC H10K 50/125; H10K 50/813

(57) ABSTRACT

A light emitting element (PX) according to an aspect of the present disclosure includes a light emitting unit (ELP), an intermediate layer (e.g., protection layer (60)) that is provided on the light emitting unit (ELP), and a color filter layer (70) that is provided on the intermediate layer (e.g., protection layer (60)), and the color filter layer (70) includes protrusion parts (71) that protrude toward the intermediate layer (e.g., protection layer (60)).

### FIELD

The present disclosure relates to a light emitting element, a display device, and an electronic device.

### BACKGROUND

In recent years, light emitting elements that each include a current-drive type light emitting unit, and a display device that includes these light emitting elements have been developed. For example, a light emitting element that uses an organic electroluminescence element (organic EL element) as the light emitting unit has attracted attention as a light emitting element that can emit light of high luminance by low-voltage direct current drive. The light emitting unit is configured by, for example, providing an organic layer including a light emission layer and the like between an anode and a cathode. Furthermore, the light emitting element includes, for example, a Color Filter layer (CF layer) and the like in addition to the light emitting unit (see, for example, Patent Literatures 1 and 2).

### CITATION LIST

### Patent Literature

Patent Literature 1: JP 2012-38677 A
Patent Literature 2: JP 2013-45542 A

### SUMMARY

### Technical Problem

Although the light emitting element controls light emission in each color, light emitted from the light emitting element is radiated as leakage light to an adjacent light emitting element (adjacent pixel), therefore color mixing occurs depending on a viewing angle, and chromaticity viewing angle characteristics lower. Furthermore, a demand of the viewing angle characteristics for the display device is high, and it is desired that it is possible to adjust the chromaticity viewing angle characteristics per pixel of the display device.

Therefore, the present disclosure proposes a light emitting element, a display device, and an electronic device that can achieve improvement of chromaticity viewing angle characteristics.

### Solution to Problem

A light emitting element according to the embodiment of the present disclosure includes: a light emitting unit; an intermediate layer that is provided on the light emitting unit; and a color filter layer that is provided on the intermediate layer, wherein the color filter layer includes a protrusion part that protrudes towards the intermediate layer.

A display device according to the embodiment of the present disclosure includes: a plurality of light emitting elements, wherein the plurality of light emitting elements each include a light emitting unit, an intermediate layer that is provided on the light emitting unit, and a color filter layer that is provided on the intermediate layer, and the color filter layer includes a protrusion part that protrudes towards the intermediate layer.

An electronic device according to the embodiment of the present disclosure includes: a display device that includes a plurality of light emitting elements, wherein the plurality of light emitting elements each include a light emitting unit, an intermediate layer that is provided on the light emitting unit, and a color filter layer that is provided on the intermediate layer, and the color filter layer includes a protrusion part that protrudes towards the intermediate layer.

### BRIEF DESCRIPTION OF DRAWINGS

FIG. 1 is a view illustrating an example of a schematic configuration of a display device according to a first embodiment.

FIG. 2 is a view illustrating an example of a schematic configuration of a light emitting element according to the first embodiment.

FIG. 3 is a view illustrating an example of a schematic configuration of a light emitting element according to the first embodiment.

FIG. 4 is a view illustrating an example of a schematic configuration of a light emitting element according to the first embodiment.

FIG. 5 is a view illustrating an example of a schematic configuration of a light emitting element according to the first embodiment.

FIG. 6 is a view for describing an effect of the light emitting element according to the first embodiment.

FIG. 7 is a view for describing an effect of the light emitting element according to the first embodiment.

FIG. 8 is a view illustrating a first modified example of the schematic configuration of the light emitting element according to the first embodiment.

FIG. 9 is a view illustrating a second modified example of the schematic configuration of the light emitting element according to the first embodiment.

FIG. 10 is a view illustrating a third modified example of the schematic configuration of the light emitting element according to the first embodiment.

FIG. 11 is a view illustrating a fourth modified example of the schematic configuration of the light emitting element according to the first embodiment.

FIG. 12 is a view illustrating a fifth modified example of the schematic configuration of the light emitting element according to the first embodiment.

FIG. 13 is a view for describing a manufacturing process of a display device according to the first embodiment.

FIG. 14 is a view for describing the manufacturing process of the display device according to the first embodiment.

FIG. 15 is a view for describing the manufacturing process of the display device according to the first embodiment.

FIG. 16 is a view for describing the manufacturing process of the display device according to the first embodiment.

FIG. 17 is a view illustrating an example of a schematic configuration of a light emitting element according to a second embodiment.

FIG. 18 is a view illustrating an example of a schematic configuration of a light emitting element according to the second embodiment.

FIG. 19 is a view illustrating a first modified example of the schematic configuration of the light emitting element according to the second embodiment.

FIG. 20 is a view illustrating a second modified example of the schematic configuration of the light emitting element according to the second embodiment.

FIG. 21 is a view illustrating a third modified example of the schematic configuration of the light emitting element according to the second embodiment.

FIG. 22 is a view illustrating a fourth modified example of the schematic configuration of the light emitting element according to the second embodiment.

FIG. 23 is a view illustrating a fifth modified example of the schematic configuration of the light emitting element according to the second embodiment.

FIG. 24 is a view illustrating a first example of an electronic device including the display device according to each embodiment.

FIG. 25 is a view illustrating a second example of the electronic device including the display device according to each embodiment.

FIG. 26 is a view illustrating the second example of the electronic device including the display device according to each embodiment.

FIG. 27 is a view illustrating a third example of the electronic device including the display device according to each embodiment.

### DESCRIPTION OF EMBODIMENTS

Hereinafter, embodiments of the present disclosure will be described in detail with reference to the drawings. Note that these embodiments do not limit a light emitting element, a display device, an electronic device, and the like according to the present disclosure. Furthermore, in each of the following embodiments, the same components will be assigned the same reference numerals, and redundant description will be omitted.

One or a plurality of embodiments (including examples and modified examples) described below can each be implemented independently. On the other hand, at least part of the plurality of embodiments described below may be combined with at least part of other embodiments as appropriate and carried out. The plurality of these embodiments may include mutually different novel features. Consequently, the plurality of these embodiments can contribute to solving mutually different objects or problems, and can exhibit mutually different effects.

The present disclosure will be described in order of items described below.
1. First Embodiment
1.1. Configuration Example of Display Device
1-2. Configuration Example of Light Emitting Element
1-3. Modified Examples of Light Emitting Element
1-4. Manufacturing Process of Display Device
1-5. Function/Effect
2. Second Embodiment
2-1. Configuration Example of Light Emitting Element
2-2. Modified Examples of Light Emitting Element
2-3. Function/Effect
3. Other Embodiment
4. Application Example
5. Supplementary Note

### 1. First Embodiment

### 1.1. Configuration Example of Display Device

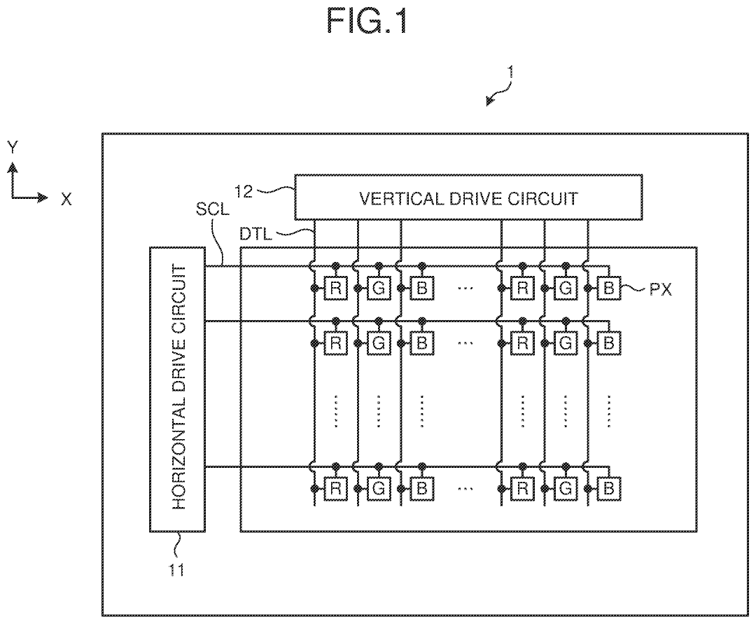

The configuration example of a display device 1 according to the first embodiment will be described with reference to FIG. 1. FIG. 1 is a view illustrating an example of a schematic configuration of the display device 1 according to the first embodiment.

As illustrated in FIG. 1, the display device 1 includes a plurality of light emitting elements PX disposed in a matrix, and a horizontal drive circuit 11 and a vertical drive circuit 12 for driving the light emitting elements PX. In the example in FIG. 1, a scan line SCL is a line for scanning the light emitting elements PX, and a signal line DTL is a line for supplying various voltages to the light emitting elements PX. Furthermore, the display device 1 also includes feeder lines (not illustrated) that supply a driving voltage or the like to the light emitting elements PX. Note that, although the horizontal drive circuit 11 and the vertical drive circuit 12 are disposed on one end sides of the display device 1 in the example in FIG. 1, arrangement thereof is not particularly limited.

For example, the M light emitting elements PX are disposed in a horizontal direction (an X direction in the drawings) and the N light emitting elements PX are disposed in a vertical direction (a Y direction in the drawings), that is, the M×N light emitting elements PX in total are disposed in a matrix. These light emitting elements PX function as respective pixels of the display device 1. In the example in FIG. 1, the light emitting elements PX that support to display red (R: wavelength 620 nm to 750 nm), display green (G: wavelength 495 nm to 570 nm), and display blue (B: wavelength 450 nm to 495 nm) are assigned reference numerals R, G, and B, respectively, and illustrated. That is, the display device 1 is a display device that can display colors.

### 1-2. Configuration Example of Light Emitting Element

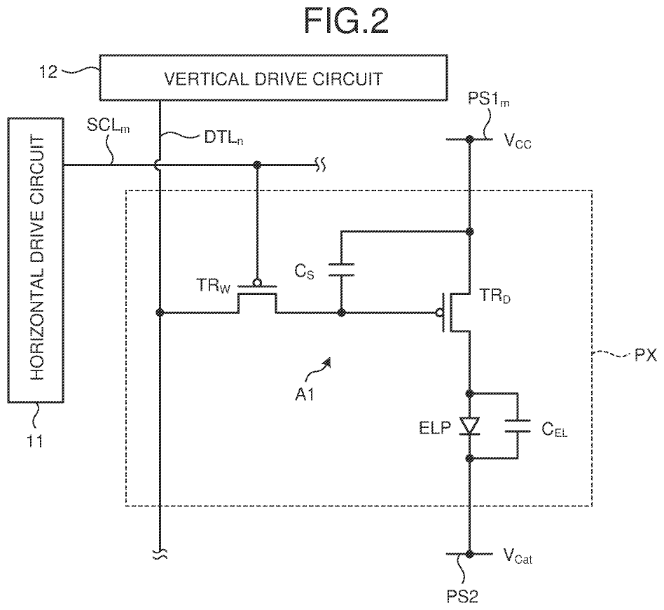

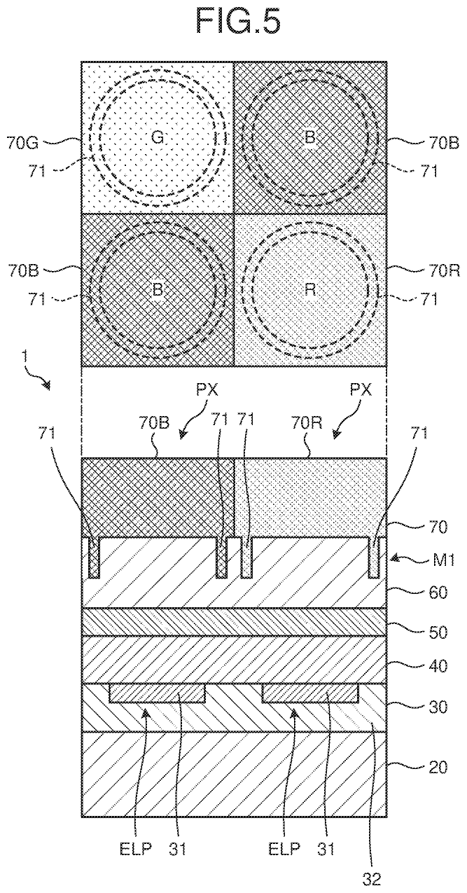

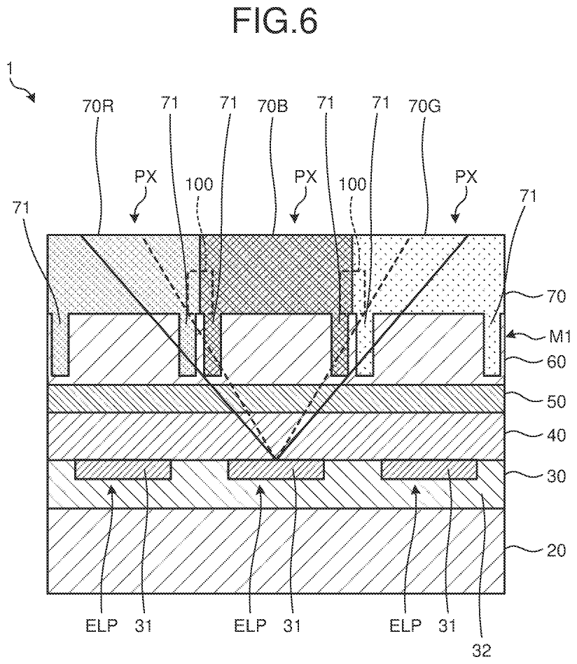

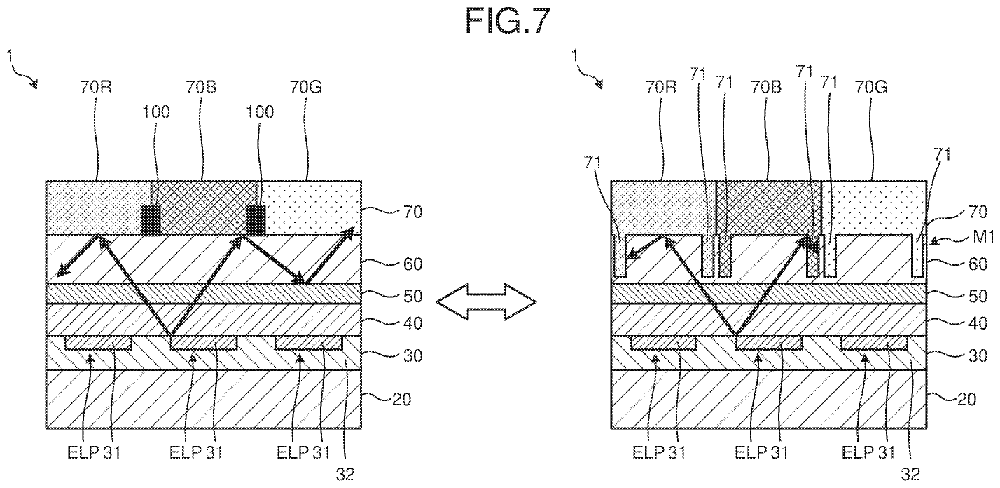

Next, a configuration example of the light emitting element PX according to the first embodiment will be described with reference to FIGS. 2 to 7. FIGS. 2 to 5 are views each illustrating an example of the schematic configuration of the light emitting element PX according to the first embodiment. FIGS. 6 and 7 are views that each describe an effect of the light emitting element PX according to the first embodiment.

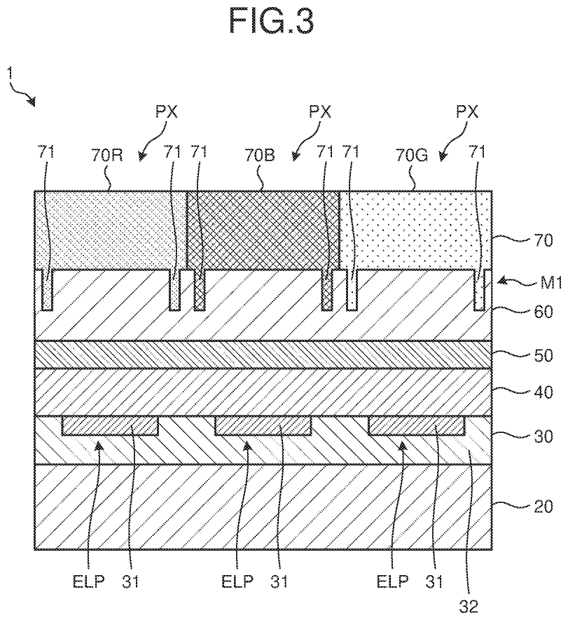

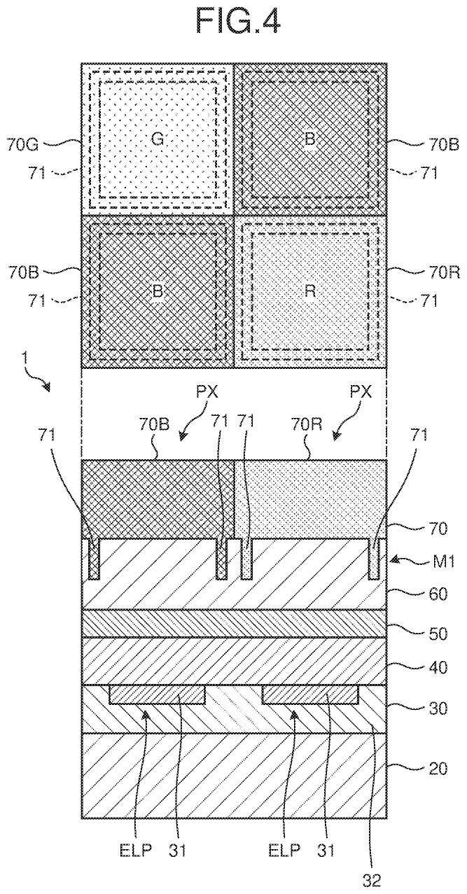

Note that, more specifically, FIG. 2 is a circuit diagram illustrating an example of the schematic configuration of the light emitting element PX, and this example in FIG. 2 indicates a line connection relationship of the one light emitting element PX, more specifically, the light emitting element PX in an m-th row and an n-th column. FIG. 3 is a cross-sectional view illustrating an example of a schematic configuration of the light emitting element PX. FIGS. 4 and 5 are a plan view and a cross-sectional view illustrating an example of a schematic configuration of the light emitting element PX.

### (Circuit Diagram)

As illustrated in FIG. 2, the light emitting element PX includes a current-drive type light emitting unit ELP, and a drive circuit A1 that controls light emission of the light emitting unit ELP. This drive circuit A1 includes at least a write transistor TR_{W} for writing a video signal, and a drive transistor TR_{D} that causes a current to flow to the light emitting unit ELP. These transistors are constituted by, for example, p-channel transistors.

The drive circuit A1 further includes a capacitance part C_{S}. The capacitance part C_{S} is used to hold a voltage (so-called gate-source voltage) of a gate electrode with respect to a source region of the drive transistor TR_{D}. At a time of light emission of the light emitting element PX, one source/drain region (a side connected to a feeder line PS1 in FIG. 2) of the drive transistor TR_{D} functions as a source region, and an other source/drain region functions as a drain region.

One electrode and an other electrode constituting the capacitance part C_{S} are connected to the one source/drain region and a gate electrode of the drive transistor TR_{D}, respectively. The other source/drain region of the drive transistor TR_{D} is connected to an anode electrode of the light emitting unit ELP.

The light emitting element PX includes the light emitting unit ELP that includes an organic electroluminescence element (organic EL element). The light emitting unit ELP is a current-drive type light emitting unit whose light emission luminance changes according to a value of a flowing current. For example, the light emitting unit ELP has a known configuration and structure that include an anode electrode, a hole transport layer, a light emission layer, an electron transport layer, a cathode electrode, and the like.

The other end (more specifically, the cathode electrode) of the light emitting unit ELP is connected to a common feeder line PS2. A predetermined voltage V_{CATH} (e.g., ground potential) is supplied to the common feeder line PS2. Note that the capacitance of the light emitting unit ELP is represented by a reference sign C_{EL}. In a case where the capacitance C_{EL} of the light emitting unit ELP is small and therefore a problem occurs at a time of driving, it is only necessary to provide an auxiliary capacitance connected in parallel to the light emitting unit ELP as necessary.

A write transistor TR_{W} includes a gate electrode that is connected to the scan line SCL, one source/drain region that is connected to the signal line (data line) DTL, and an other source/drain region that is connected to the gate electrode of the drive transistor TR_{D}. As a result, a signal voltage from the signal line DTL is written in the capacitance part C_{S} via the write transistor TR_{W}.

As described above, the capacitance part C_{S} is connected between the one source/drain region and the gate electrode of the drive transistor TR_{D}. The one source/drain region of the drive transistor TR_{D} is applied a power supply voltage V_{CC} from an unillustrated power supply unit via a feeder line PS1ₘ. When a video signal voltage V_{Sig} from the signal line DTL is written into the capacitance part C_{S} via the write transistor TR_{W}, the capacitance part C_{S} holds a voltage such as (V_{CC}−V_{Sig}) as a gate-to-source voltage of the drive transistor TR_{D}. A drain current I_{ds} expressed by following equation (1) flows through the drive transistor TR_{D}, and the light emitting unit ELP emits light with luminance corresponding to a current value.

$${I}_{ds} = k \cdot μ \cdot {( ( {V}_{CC} - {V}_{Sig} ) - \vert {V}_{th} \vert )}^{2} \qquad ( 1 )$$

Here, μ represents effective mobility, L represents a channel length, W represents a channel width, Vₜₕ represents a threshold voltage, Cₒₓ represents (relative permittivity of gate insulation layer)×(dielectric constant of vacuum)/(thickness of gate insulation layer), and k≡(½)·(W/L)·Cₒₓ holds.

### (Cross-Sectional View)

As illustrated in FIG. 3, the display device 1 includes the plurality of light emitting elements PX. These light emitting elements PX each include an anode layer 30, an organic layer 40, a cathode layer 50, a protection layer 60, and a Color Filter layer (CF layer) 70. These anode layer 30, organic layer 40, cathode layer 50, protection layer 60, and Color Filter layer (CF layer) 70 are sequentially laminated on a substrate 20 to form each light emitting element PX.

The substrate 20 is a support body that supports the plurality of light emitting elements PX aligned on one surface. Note that, although not illustrated, the substrate 20 may include, for example, a control circuit (e.g., drive circuit A1) that controls driving of each light emitting element PX, a power supply circuit that supplies power to each light emitting element PX, a multilayer wiring layer that includes various wirings, and the like.

The anode layer 30 is laminated on the substrate 20. This anode layer 30 includes a plurality of anode electrodes 31 and an insulation layer 32. Each anode electrode 31 is provided on one surface (the upper surface in FIG. 3) of the insulation layer 32 per light emitting element PX. For example, the anode electrode 31 is formed of a metal material. The anode electrode 31 corresponds to a first electrode. The insulation layer 32 partitions each anode electrode 31. The insulation layer 32 may include, for example, a reflection layer or the like.

The organic layer 40 is laminated on the anode layer 30. This organic layer 40 includes at least a light emission layer, and is formed to emit, for example, white light. Note that the organic layer 40 is illustrated as one layer in the example in FIG. 3, yet is formed by a plurality of layers including the light emission layer.

The cathode layer 50 is laminated on the organic layer 40. This cathode layer 50 is formed of, for example, a material (e.g., transparent conductive material) that has high light transmissivity and conductivity. The cathode layer 50 functions as a cathode electrode, and corresponds to a second electrode.

Here, each light emitting unit ELP is formed by sequentially laminating the organic layer 40 and the cathode layer 50 on the anode electrode 31 provided per light emitting element PX. Light emitted from the organic layer 40 is emitted from the surface of the organic layer 40 on the cathode layer 50 side. The planar shape of the light emission surface of the light emitting element PX is generally similar to the planar shape of the anode electrode 31.

Furthermore, each light emitting unit ELP is partitioned by the insulation layer 32. That is, the insulation layer 32 functions as a partition wall part that exists between the adjacent anode electrodes 31. Note that, for example, the drive circuit A1 (see FIG. 2) is formed in the substrate 20 per light emitting unit ELP, and each anode electrode 31 is electrically connected to the drive circuit A1. For example, each anode electrode 31 is electrically connected to the drive circuit A1 via a conductive part (not illustrated) such as a via provided in the insulation layer 32. The drive circuit A1 controls a light emission state of the light emitting unit ELP according to a signal from the outside.

The protection layer 60 is laminated on the cathode layer 50. This protection layer 60 protects the inside of the display device 1 from external environment, and prevents moisture, oxygen, and the like from entering, for example, the organic layer 40. The protection layer 60 is made of, for example, a material that has high light transmissivity and a high gas barrier property. As this material, for example, silicon oxide (SiOₓ), silicon nitride (SiNₓ), aluminum oxide (AlOₓ), or the like is used. Furthermore, the protection layer 60 may be formed as a laminated film of the above-described material or the like to improve protection capability such as the gas barrier property or to adjust the refractive index. The protection layer 60 corresponds to an intermediate layer.

The color filter layer 70 is laminated on the protection layer 60. More specifically, the color filter layer 70 includes a color filter 70R for displaying red, a color filter 70B for displaying blue, and a color filter 70G for displaying green. Hence, the display device 1 includes the light emitting elements PX for displaying red, the light emitting elements PX for displaying blue, and the light emitting elements PX for displaying green. Note that, for example, a lens layer including a plurality of microlenses may be provided on the color filter layer 70.

Each of the color filters 70R, 70B, and 70G includes a protrusion part 71. Each of these protrusion parts 71 is formed in a region on the outer periphery side (outer periphery region) instead of the center side of each of the color filters 70R, 70B, and 70G, and extend in a depth direction (a lower direction in FIG. 3) from each of the color filters 70R, 70B, and 70G toward the protection layer 60. In the example in FIG. 3, each protrusion part 71 extends in parallel to the depth direction. This protrusion part 71 makes the surface of the color filter layer 70 on the protection layer 60 side a protruding/recessed shape. Note that the protrusion part 71 is provided in a groove M1 formed in the protection layer 60.

In this regard, the length in the depth direction of the protrusion part 71, the width in a planar direction (a left-right direction in FIG. 3) of the protrusion part 71, and the shape of the protrusion part 71 are the same between the color filters 70R, 70B, and 70G. For example, the length in the depth direction of the protrusion part 71 is desirably half or more of the length in the depth direction of the protection layer 60. Note that the length in the depth direction of the protrusion part 71, the width in the planar direction of the protrusion part 71, and the shape of the protrusion part 71 may be the same or may be different between the color filters 70R, 70B, and 70G, and are set according to, for example, a desired angular viewing angle.

Furthermore, the protrusion part 71 extends in parallel to the depth direction, yet is not limited thereto, and may extend obliquely with respect to, for example, the depth direction. Furthermore, the protrusion part 71 is formed so as to be located on an outer side of the outer shape of the anode electrode 31 in plan view, yet is not limited thereto, and may be formed so as to be located on an inner side of the outer shape of the anode electrode 31 in plan view.

Furthermore, the protrusion part 71 of the color filter 70R is a red color filter that has the same color as the color filter 70R. The same also applies to the other color filters 70B and 70G. That is, the protrusion part 71 of the color filter 70B is a blue color filter that has the same color as the color filter 70B, and the protrusion part 71 of the color filter 70G is a green color filter that has the same color as the color filter 70G.

Note that the protrusion part 71 of the color filter 70R is a red color filter that has the same color as the color filter 70R, yet is not limited thereto, and may be, for example, a color filter that has a different color from that of the color filter 70R (e.g., a color filter that has a similar color to that of the color filter 70R). The same also applies to the other color filters 70B and 70G.

### (Plan View)

As illustrated in FIGS. 4 and 5, the protrusion part 71 is formed in a ring shape in plan view. More specifically, the protrusion part 71 may be formed in a rectangular ring shape in plan view as illustrated in FIG. 4, or may be formed in a circular ring shape in plan view as illustrated in FIG. 5. Note that the protrusion part 71 is formed in, for example, a region on an outer periphery side (outer periphery region) avoiding a region on a center side (center region) of a pixel. In the example in FIG. 4, the protrusion part 71 is formed in a square ring shape. In this case, the protrusion part 71 (groove M1) is formed along a boundary region of each light emitting element PX (each pixel). Note that a color filter array (color pattern) is a GBBR array in the examples in FIGS. 4 and 5.

Here, the size (outer dimension) in the planar direction of the ring-shaped protrusion part 71 is desirably the size (outer dimension) of the anode electrode 31 or more in plan view. Furthermore, the protrusion part 71 is desirably formed in the same shape as the outer shape of the anode electrode 31 in plan view. This is because the planar shape of the light emission surface of the light emitting unit ELP has the shape that is generally similar to the planar shape of the anode electrode 31, and therefore it is desirable to match the planar size, the planar shape, and the like of the protrusion part 71 with this planar shape of the light emission surface. The anode electrode 31 is formed in the square shape in plan view in the example in FIG. 4, and is formed in the circular shape in plan view in the example in FIG. 5.

According to the above-described configuration example of the light emitting element PX, the color filter layer 70 includes the protrusion part 71 that protrudes toward the protection layer 60 that is an example of the intermediate layer. Consequently, the protrusion part 71 functions as an anchor, so that it is possible to improve adhesion of the color filter layer 70 to the protection layer 60. Furthermore, part of the color filter layer 70 that is a light shielding layer (light shielding part) approaches the light emission surface, so that it is possible to improve the light shielding property in a region of a large viewing angle, and prevent color mixing. For example, when light generated by the light emitting unit ELP associated with the blue color filter 70B is incident on the protrusion part 71 of the blue color filter 70B, only light having a blue wavelength passes through this protrusion part 71, yet does not pass through the respective color filters 70R and 70G adjacent to the blue color filter 70B. In this way, the protrusion parts 71 improve the light shielding property, so that it is possible to prevent color mixing.

Here, as illustrated in FIG. 6, a suppression angle that makes it difficult to prevent color mixing spreads to a solid line with respect to a broken line indicating a suppression angle of a type that is provided with barriers 100 in the color filter layer 70 in a comparative example. That is, color mixing on the high viewing angle side is prevented, and the chromaticity viewing angle characteristics are improved. Furthermore, regarding the luminance viewing angle, the luminance lowers in a region of the large viewing angle, so that it is possible to suppress light that can transmit even in a small light shielding layer. Furthermore, as illustrated in FIG. 7, it is possible to block light leaking in a lateral direction using the protection layer 60 as a waveguide, and it is possible to further suppress an influence of color mixing. Here, the left side in FIG. 7 is a type that is provided with the barriers 100 in the color filter layer 70 (comparative example), and the right side in FIG. 7 is a type that is provided with the protrusion parts 71 in the protection layer 60 according to the present embodiment.

### 1-3. Modified Examples of Light Emitting Element

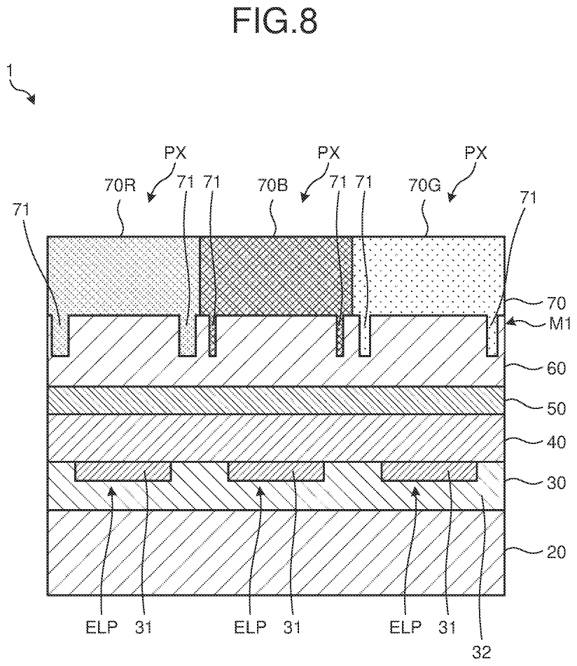

A first modified example to a fifth modified example of the light emitting element PX according to the first embodiment will be described with reference to FIGS. 8 to 12. FIGS. 8 to 12 are views (cross-sectional views) each illustrating the modified example of the schematic configuration of the light emitting element PX according to the first embodiment. Note that any one of the first modified example to the fifth modified example can be combined.

### First Modified Example

As illustrated in FIG. 8, in the first modified example, the widths in the planar direction (the left-right direction in FIG. 8) of the ring-shaped protrusion parts 71 are different between the respective color filters 70R, 70B, and 70G. In the example in FIG. 8, the widths in the planar direction of the ring-shaped protrusion part 71 increase in order of the color filters 70B, 70G, and 70R. Note that the width in the planar direction of the ring-shaped protrusion part 71 is an edge width (outer dimension-inner dimension).

### Second Modified Example

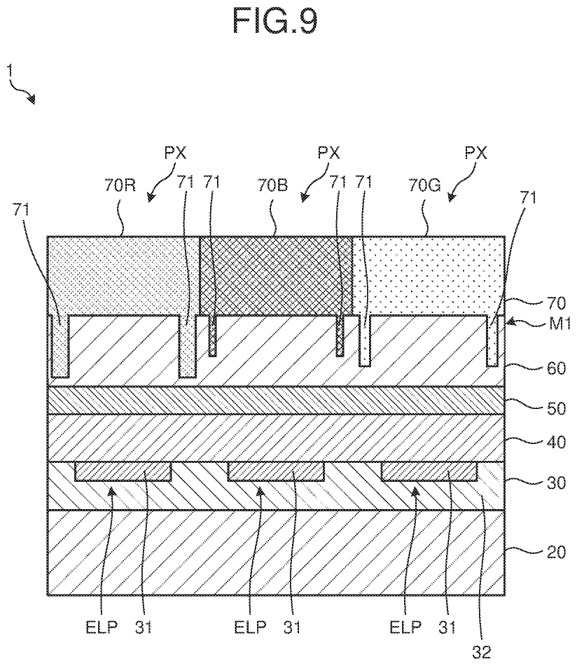

In addition to first modified example, as illustrated in FIG. 9, the length in the depth direction of the protrusion part 71 (the lower direction in FIG. 9) is different between the respective color filters 70R, 70B, and 70G in the second modified example. In the example in FIG. 9, the lengths in the depth direction of the protrusion parts 71 increase in order of the respective color filters 70B, 70G, and 70R.

### Third Modified Example

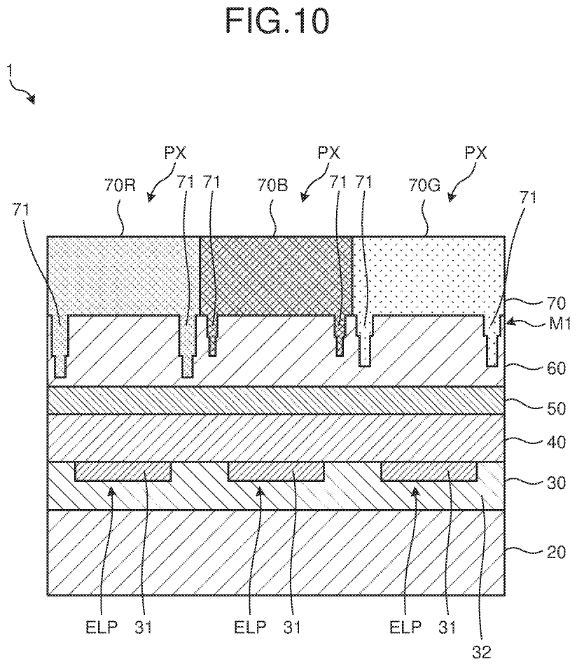

In addition to the first modified example and the second modified example, as illustrated in FIG. 10, the widths in the planar direction (the left-right direction in FIG. 10) of the ring-shaped protrusion parts 71 of the respective color filters 70R, 70B, and 70G change in the middle of the protrusion parts 71 in the third modified example. In the example in FIG. 10, the thickness in the planar direction of the protrusion part 71 changes stepwise, yet is not limited thereto, and may gradually change.

### Fourth Modified Example

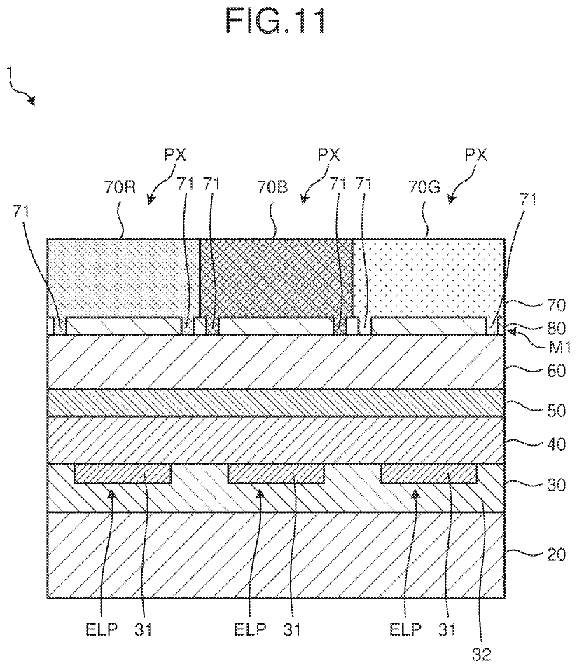

As illustrated in FIG. 11, in the fourth modified example, the light emitting element PX includes a planarization layer 80. This planarization layer 80 is provided between the protection layer 60 and the color filter layer 70. The planarization layer 80 is formed of, for example, a material (e.g., transparent resin material) that has high light transmissivity. The planarization layer 80 corresponds to the intermediate layer.

The color filter layer 70, that is, the respective color filters 70R, 70B, and 70G include the protrusion parts 71 that protrude toward the planarization layer 80. As a result, the surface of the color filter layer 70 on the planarization layer 80 side has a protruding/recessed shape.

### Fifth Modified Example

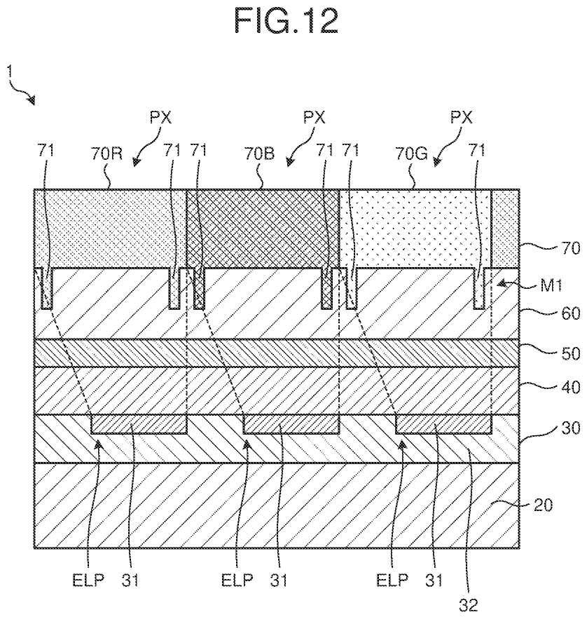

As illustrated in FIG. 12, in the fifth modified example, each of the color filters 70R, 70B, and 70G is shifted in the planar direction (the left-right direction in FIG. 12) with respect to the corresponding anode electrode 31. In the example in FIG. 12, each of the color filters 70R, 70B, and 70G is shifted in a left direction with respect to the corresponding anode electrode 31.

For example, in a panel of display device 1, the viewing angle characteristics change between a panel center region (center portion) and a panel outer periphery region (outer periphery end part). Hence, the color filters 70R, 70B, and 70G may be shifted, that is, the color filter patterns may be offset and aligned according to the viewing angle characteristics in the panel of the display device 1. More specifically, the color filters 70R, 70B, and 70G may be shifted toward the center side (or the opposite side depending on cases) of the panel of the display device 1 at the panel end part of the display device 1.

### 1-4. Manufacturing Process of Display Device

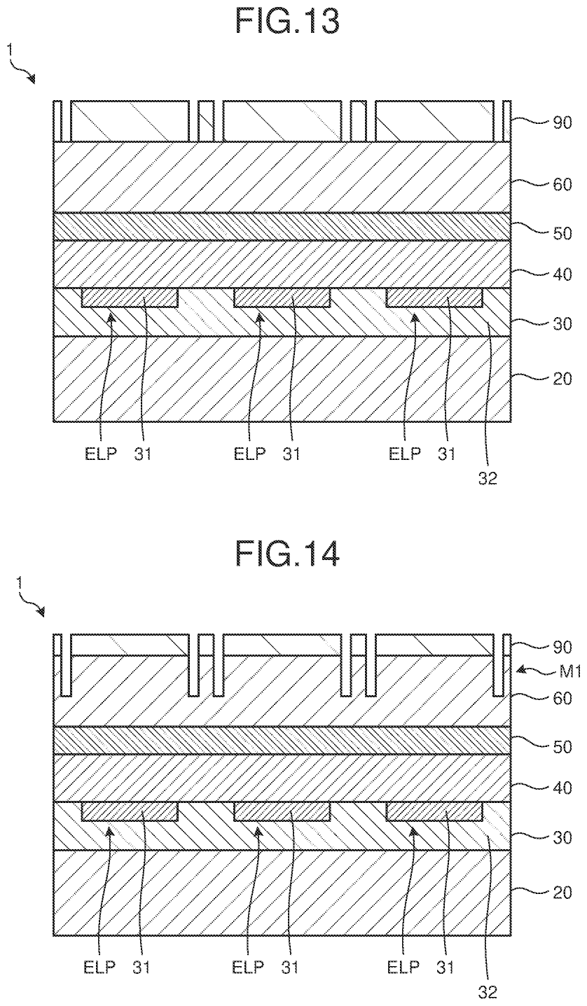

A manufacturing process of the display device 1 according to the first embodiment will be described with reference to FIGS. 13 to 16. FIGS. 13 to 16 are views that each describe the manufacturing process of the display device 1 according to the first embodiment.

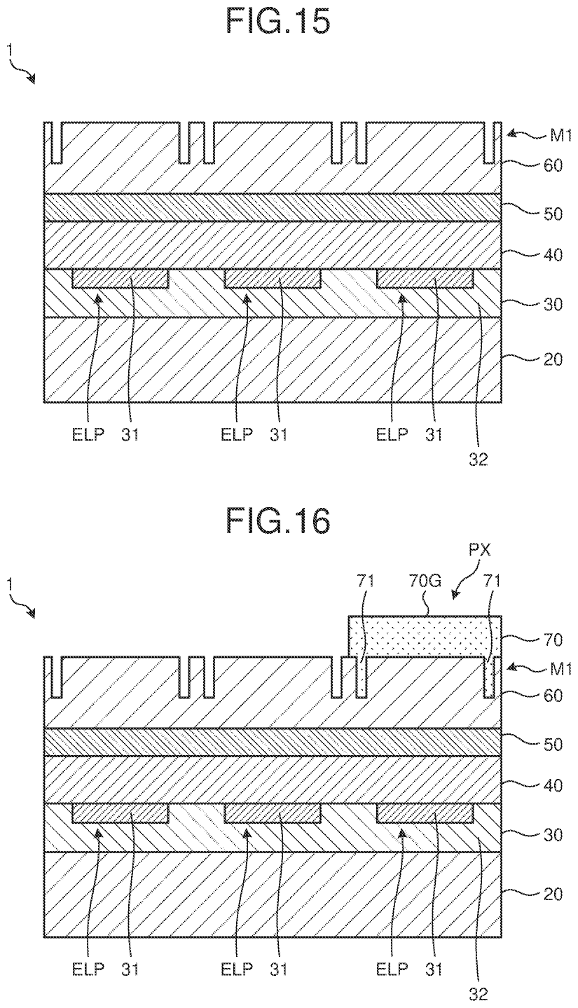

As illustrated in FIG. 13, the anode layer 30, the organic layer 40, the cathode layer 50, and the protection layer 60 are sequentially formed on the substrate 20. Next, a resist layer 90 is formed on this protection layer 60, and patterning is performed using a photoresist. As illustrated in FIG. 14, the patterned portion is processed by dry etching. As a result, the plurality of grooves M1 (e.g., ring-shaped grooves M1) are formed in the protection layer 60. Next, as illustrated in FIG. 15, the resist layer 90 is peeled off from the protection layer 60. Subsequently, as illustrated in FIG. 16, the color filters 70G, 70R, and 70B associated with the respective light emitting units ELP, that is, the respective pixels are sequentially formed by a known method to form the color filter layer 70. Note that a protection film formed by Atomic Layer Deposition (ALD) film formation may be formed on the processed surface to repair defects by processing such as dry etching and further improve protection capability.

In such a manufacturing process, the protection layer 60 is formed, then each groove M1 is formed by dry etching, and the protrusion part 71 is formed in each groove M1 at the same time as the time of formation of the color filters 70G, 70R, and 70B. Consequently, it is possible to form the protrusion parts 71 that protrude toward the protection layer 60 by a simple process. It is possible to, for example, form each groove M1 at a time, achieve a single processing process, and decrease a difficulty level of the process procedure. Note that, although each groove M1 is processed using dry etching in the protection layer 60 such as an inorganic film, the pattern may be directly formed and each groove M1 may be formed in a case where a photosensitive material is used for an organic film such as the planarization layer 80. Note that the shape of the groove M1, that is, formation of the recess shape is made of a material of the base layer of the color filter layer 70, and therefore is not limited.

### 1-5. Function/Effect

As described above, according to the first embodiment, the light emitting element PX includes the light emitting unit ELP that emits light, the intermediate layer (e.g., the protection layer 60 or the planarization layer 80) that is provided on the light emitting unit ELP, and the color filter layer 70 that is provided on the intermediate layer, and the color filter layer 70 includes the protrusion parts 71 that protrude toward the intermediate layer. Consequently, part of the color filter layer 70 that serves as the light shielding part approaches the light emission surface, so that the light shielding property improves in a region of the large viewing angle, it is possible to prevent color mixing, and consequently it is possible to achieve improvement of the chromaticity viewing angle characteristics. Furthermore, the protrusion parts 71 function as the anchors, so that it is possible to achieve improvement of adhesion of the color filter layer 70 to the intermediate layer.

Furthermore, the protrusion part 71 may be provided in the groove M1 formed in the intermediate layer. Consequently, it is possible to form the protrusion part 71 in the intermediate layer by the simple manufacturing process that uses the groove M1.

Furthermore, the protrusion part 71 may be formed in a ring shape in plan view. Consequently, it is possible to reliably achieve improvement of the chromaticity viewing angle characteristics and, moreover, improvement of adhesion of the color filter layer 70 to the intermediate layer.

Furthermore, the light emitting unit ELP may include the first electrode (e.g., anode electrode 31), and the protrusion part 71 may be formed in the same shape as that of the outer shape of the first electrode in plan view. Consequently, it is possible to reliably achieve improvement of the chromaticity viewing angle characteristics.

Furthermore, the light emitting unit ELP may include the first electrode (e.g., anode electrode 31), and the protrusion part 71 may be formed so as to be located on the outer side of the outer shape of the first electrode in plan view. Consequently, it is possible to reliably achieve improvement of the chromaticity viewing angle characteristics.

Furthermore, the protrusion part 71 may be a color filter that has the same color as that of the color filter layer 70. Consequently, it is possible to reliably prevent color mixing in a region of the large viewing angle.

Furthermore, the protrusion part 71 may be a color filter that has a different color from that of the color filter layer 70 (e.g., a color filter that has a color similar to that of the color filter layer 70). Consequently, it is possible to prevent color mixing in a region of the large viewing angle.

Furthermore, the length in the depth direction or the width in the planar direction of the protrusion part 71 may be set according to a desired chromaticity viewing angle. Consequently, it is possible to reliably achieve improvement of the chromaticity viewing angle characteristics.

Furthermore, the shape of the protrusion part 71 may be set according to a desired chromaticity viewing angle. Consequently, it is possible to reliably achieve improvement of the chromaticity viewing angle characteristics.

Furthermore, the color filter layer 70 may be shifted in the planar direction with respect to the light emitting unit ELP (see FIG. 12). Consequently, it is possible to obtain the chromaticity viewing angle characteristics matching a position in the panel of the display device 1, and reliably achieve improvement of the chromaticity viewing angle characteristics.

Furthermore, the individual lengths in the depth direction or the individual widths in the planar direction of the protrusion parts 71 of the respective light emitting elements PX may be different from each other (see FIGS. 9 and 10). Consequently, it is possible to reliably achieve improvement of the chromaticity viewing angle characteristics.

Furthermore, the individual shapes of the protrusion parts 71 of the respective light emitting elements PX may be different from each other (see FIG. 10). Consequently, it is possible to reliably achieve improvement of the chromaticity viewing angle characteristics.

### 2. Second Embodiment

### 2-1. Configuration Example of Light Emitting Element

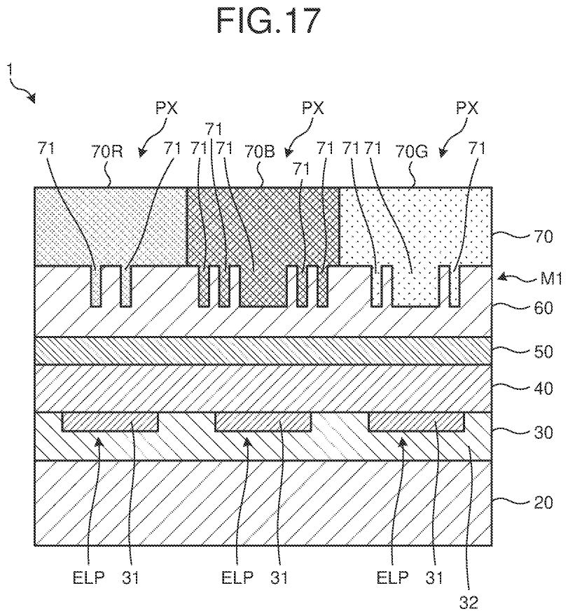

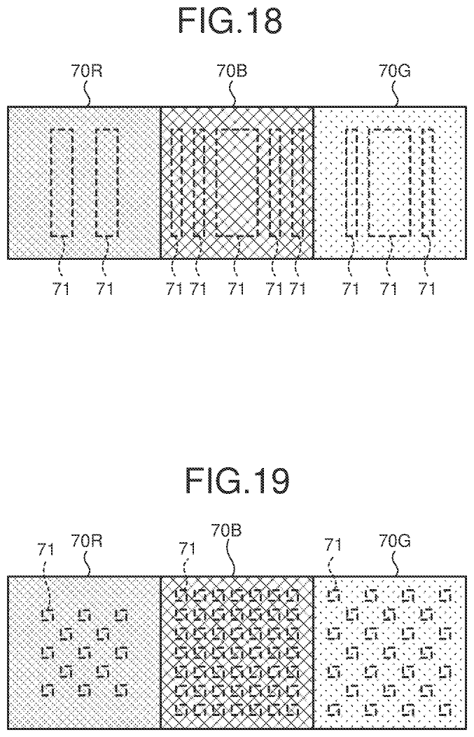

The configuration example of a light emitting element PX according to the second embodiment will be described with reference to FIGS. 17 and 18. FIGS. 17 and 18 are views each illustrating an example of a schematic configuration of the light emitting element PX according to the second embodiment. More specifically, FIG. 17 is a cross-sectional view illustrating the example of the schematic configuration of the light emitting element PX, and FIG. 18 is a plan view illustrating the example of the schematic configuration of the light emitting element PX.

As illustrated in FIGS. 17 and 18, in the second embodiment, each of color filters 70R, 70B, and 70G includes a plurality of protrusion parts 71. Each protrusion part 71 is provided, for example, not on the outer periphery side of the light emitting element PX (a region on a boundary side between pixels), but in a region on the center side (center region). In the examples in FIGS. 17 and 18, the color filter 70R includes the two protrusion parts 71, the color filter 70B includes the five protrusion parts 71, and the color filter 70G includes the three protrusion parts 71. As illustrated in FIG. 18, these protrusion parts 71 are formed in rectangular shapes in plan view, and a pattern of the protrusion parts 71 (a pattern of grooves M1) is a stripe pattern. Note that the individual widths in the planar direction (the left-right direction in FIGS. 17 and 18) of the protrusion parts 71 may be the same or may be different.

According to such a configuration, the plurality of protrusion parts 71 are formed in a light emission region on a light emitting unit ELP of a protection layer 60 that is the base of a color filter layer 70. As a result, the surface of the color filter layer 70 on the protection layer 60 side has a protruding/recessed shape. Consequently, it is possible to change the luminance viewing angle characteristics and the chromaticity viewing angle characteristics in pixels by providing each protrusion part 71 in the protection layer 60. Note that the respective characteristics are different per color, so that it is possible to change the pattern (protruding/recessed pattern) of the protrusion parts 71 and finely adjust the respective characteristics. By, for example, providing a pattern difference between the protrusion parts 71 at the center part and the outer peripheral part of the light emitting element PX (pixel) according to a viewing angle, it is possible to improve the chromaticity viewing angle characteristics.

Here, light emitted by a white organic EL element passes through the color filter layer 70, and is subjected to color conversion. According to the distance over which the light has passed through the color filter layer 70, the luminance lowers, and the color deepens. By forming the plurality of protrusion parts 71 (protruding/recessed shape) in the protection layer 60 that is the base without changing the film thickness of the color filter layer 70, the thickness (film thickness) of the color filter layer 70 is increased, so that it is possible to adjust luminance and chromaticity of passing light. The demand of the viewing angle characteristics for the display device 1 is high, and it is possible to prevent deterioration of the characteristics by finely adjusting the luminance viewing angle characteristics and the chromaticity viewing angle characteristics.

### 2-2. Modified Examples of Light Emitting Element

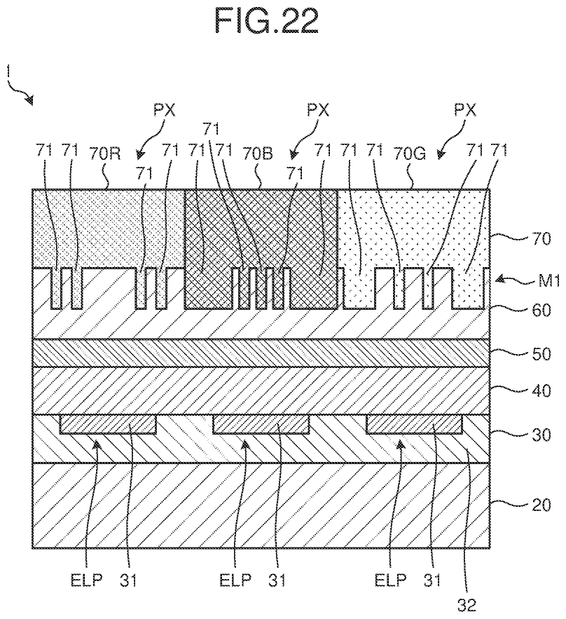

A first modified example to a fifth modified example of the light emitting element PX according to the second embodiment will be described with reference to FIGS. 19 to 23. FIGS. 19 to 23 are views each illustrating the modified example of a schematic configuration of the light emitting element PX according to the second embodiment. More specifically, FIGS. 19 to 21 and 23 are plan views each illustrating an example of the schematic configuration of the light emitting element PX, and FIG. 22 is a cross-sectional view illustrating an example of the schematic configuration of the light emitting element PX. Note that any one of the first modified example to the fifth modified example can be combined.

### First Modified Example

As illustrated in FIG. 19, in the first modified example, each of the color filters 70R, 70B, and 70G includes the plurality of protrusion parts 71 that have quadrangular shapes in plan view. In the example in FIG. 19, the color filter 70R includes the 13 protrusion parts 71, the color filter 70B includes the 49 protrusion parts 71, and the color filter 70G includes the 25 protrusion parts 71. A pattern of the protrusion parts 71 (the pattern of the grooves M1) is a dot pattern.

### Second Modified Example

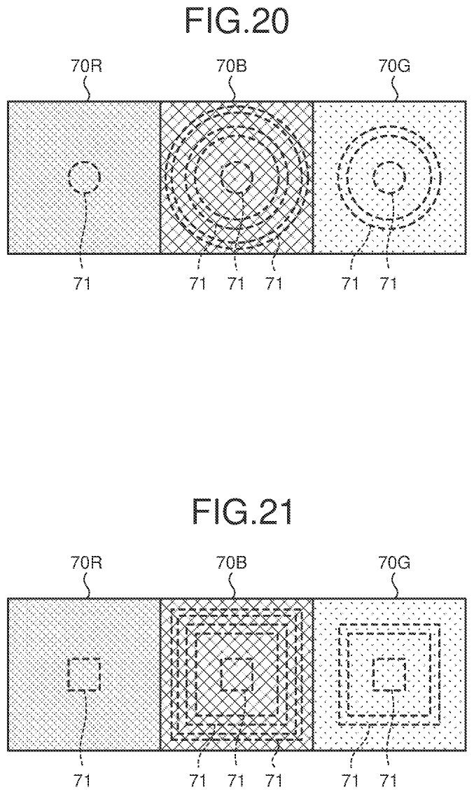

As illustrated in FIG. 20, in the second modified example, the color filter 70R includes the one protrusion part 71 that has a circular shape in plan view. The color filter 70B includes the one protrusion part 71 that has a circular shape in plan view, and the two protrusion parts 71 that have circular ring shapes in plan view. The color filter 70G includes the one protrusion part 71 that has a circular shape in plan view, and the one protrusion part 71 that has a circular ring shape in plan view. In the example in FIG. 20, a pattern of the protrusion parts 71 (a pattern of the grooves M1) is a concentric pattern.

### Third Modified Example

As illustrated in FIG. 21, in the third modified example, the color filter 70R includes the one protrusion part 71 that has a rectangular shape in plan view. The color filter 70B includes the one protrusion part 71 that has a rectangular shape in plan view, and the two protrusion parts 71 that have rectangular ring shapes in plan view. The color filter 70G includes the one protrusion part 71 that has a rectangular shape in plan view, and the one protrusion part 71 that has a rectangular ring shape in plan view. In the example in FIG. 21, a pattern of the protrusion parts 71 (a pattern of the grooves M1) is a concentric rectangular pattern.

Here, in a case where, for example, the color filters 70R, 70B, and 70G are formed as square pixels, a stripe pattern, a dot pattern, a concentric circular pattern, a concentric rectangular pattern, or the like can be used as the pattern of the protrusion parts 71 (the pattern of the grooves M1) according to optical characteristics as illustrated in FIGS. 18 to 21. Note that this pattern is desirably formed to match with the shape of the anode electrode 31 in plan view, yet does not need to depend on the shape of the anode electrode 31 in plan view, and the pixel may be other than the square pixel.

### Fourth Modified Example

As illustrated in FIG. 22, in the fourth modified example, each protrusion part 71 is also provided in, for example, the outer periphery region in addition to the center region of the optical element PX. Consequently, it is also possible to increase regions of the protrusion parts 71 not at the pixel center, but at the pixel outer periphery portion depending on the light emission distribution using, for example, a cavity structure or the like. Furthermore, the overall film thickness amount is controlled according to the characteristics of the color filter layer 70, so that it is also possible to adjust colors by increasing the regions of the protrusion parts 71. Depending on an anode shape and the cavity structure, light emission may be stronger at the periphery of the pixel than at the center of the pixel, so that it is possible to change the pattern of the protrusion parts 71 (the pattern of the grooves M1) in the pixel according to the light emission intensity.

### Fifth Modified Example

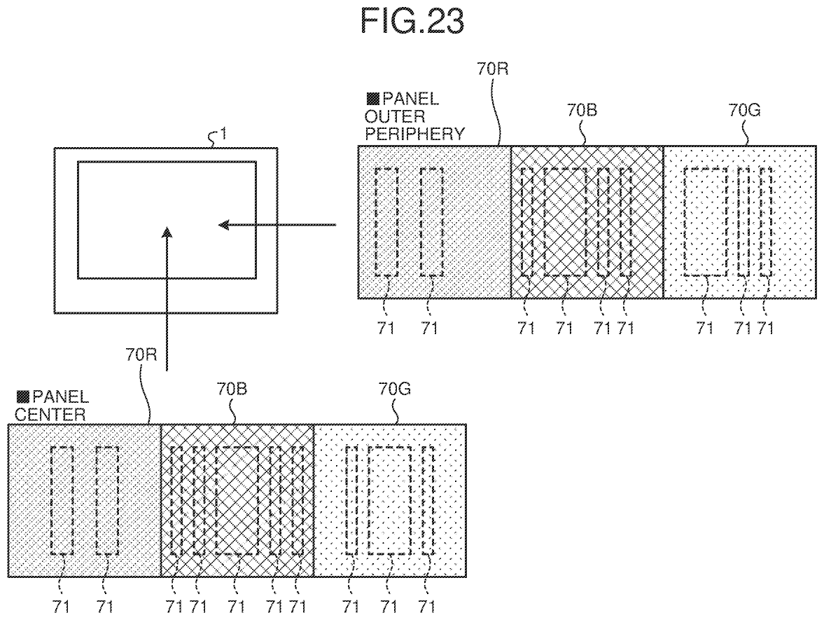

As illustrated in FIG. 23, in the fifth modified example, the stripe pattern illustrated in FIG. 18 is used in the panel center region of the display device 1. In the panel outer periphery region of the display device 1, and in the color filter 70R, the stripe pattern illustrated in FIG. 18 is shifted in the planar direction (the left direction in FIG. 23) with respect to the anode electrode 31. Furthermore, a stripe pattern different from the stripe pattern illustrated in FIG. 18 is used in each of the color filters 70B and 70G.

Here, in the display device 1, the viewing angle characteristics (luminance viewing angle characteristics and chromaticity viewing angle characteristics) are different between the panel center portion and the panel outer periphery portion. Luminance and chromaticity (e.g., color tone) are adjusted according to the viewing angle at the inner and outer peripheries of the panel, so that it is possible to prevent degradation of the viewing angle characteristics by changing the offset and the pattern in the panel of the display device 1.

Note that the second embodiment, the first to fifth modified examples according to the second embodiment, the first embodiment, the first to fifth modified examples according to the first embodiment, and the like can be combined as appropriate. Even in such a case, the length in the depth direction of each protrusion part 71, the width in the planar direction of each protrusion part 71, and the shape of each protrusion part 71 may be mutually the same or may be different from each other, and are set according to, for example, a desired angular viewing angle or a desired luminance viewing angle.

### 2-3. Function/Effect

As described above, according to the second embodiment, it is possible to obtain the effect similarly to the first embodiment. For example, according to the second embodiment, the color filter layer 70 includes the plurality of protrusion parts 71. Consequently, it is possible to achieve improvement of the chromaticity viewing angle characteristics by changing the arrangement of the protrusion parts 71 in the light emitting element PX (pixel). Furthermore, by changing the pattern of the protrusion parts 71 (the pattern of the grooves M1) and the length in the depth direction of each protrusion part 71 per each pixel, it is possible to adjust luminance, chromaticity, and the like, and achieve improvement of the luminance viewing angle characteristics and the chromaticity viewing angle characteristics. Furthermore, the plurality of protrusion parts 71 function as anchors, so that it is possible to achieve improvement of adhesion of the color filter layer 70 to the intermediate layer (e.g., the protection layer 60 or a planarization layer 80).

Furthermore, each protrusion part 71 may be formed in a rectangular shape or a ring shape in plan view. Consequently, it is possible to reliably achieve improvement of the chromaticity viewing angle characteristics and the luminance viewing angle characteristics, and, moreover, improvement of adhesion of the color filter layer 70 to the intermediate layer.

Furthermore, the individual lengths in the depth direction or the individual widths in the planar direction of the respective protrusion parts 71 may be different from each other. Consequently, it is possible to reliably achieve improvement of the chromaticity viewing angle characteristics and the luminance viewing angle characteristics.

Furthermore, the individual shapes of the respective protrusion parts 71 may be different from each other. Consequently, it is possible to reliably achieve improvement of the chromaticity viewing angle characteristics and the luminance viewing angle characteristics.

Furthermore, the individual lengths in the depth direction or the individual widths in the planar direction of the respective protrusion parts 71 may be set according to a desired chromaticity viewing angle or a desired luminance viewing angle. Consequently, it is possible to reliably achieve improvement of the chromaticity viewing angle characteristics and the luminance viewing angle characteristics.

Furthermore, the individual shapes of the respective protrusion parts 71 or the number of the respective protrusion parts 71 may be set according to a desired chromaticity viewing angle or a desired luminance viewing angle. Consequently, it is possible to reliably achieve improvement of the chromaticity viewing angle characteristics and the luminance viewing angle characteristics.

### 3. Other Embodiment

Processing according to the above-described embodiments (or modified examples) may be performed in various different modes (modified examples) other than the above embodiments. The processing procedures, the specific names, and the information including the various items of data and the parameters illustrated in the above description and drawings can be arbitrarily changed unless otherwise designated. For example, the various pieces of information illustrated in each drawing are not limited to the illustrated information. Furthermore, the above-described embodiments (or modified examples) can be combined as appropriate within a range where the processing contents does not contradict each other. Note that the effects described in the description are merely illustrative or exemplary, and are not restrictive.

For example, a color filter may be configured to include a coloring material and/or fine particles that constitute quantum dots. Furthermore, the color filter may be formed using a known resist material to which a desired coloring material or the like is added. As the coloring material, known pigments and dyes can be used. Furthermore, the fine particles constituting the quantum dots are not particularly limited, and, for example, light emitting semiconductor nanoparticles may be used. The color filter including the coloring material displays a color by allowing transmission of light in a target wavelength range among light from a light emitting element PX. Furthermore, the color filter containing the fine particles constituting the quantum dots displays a color by converting the wavelength of the light from the light emitting element PX.

Furthermore, as a material that forms the optical element PX, a suitable material is appropriately selected from transparent organic materials or inorganic materials and used. The optical element PX is obtained by, for example, forming a resist on a transparent material layer and etching the resist.

Furthermore, in a display device 1, each light emitting element PX may be associated and provided with at least one optical element (e.g., microlens), or may be associated and provided with a plurality of optical elements.

Furthermore, as a light emitting unit ELP, an LED element, a semiconductor laser element, or the like can be used in addition to an organic electroluminescence element. These elements are configured using known materials and methods. In particular, it is preferable to employ a configuration including the organic electroluminescence element as the light emitting unit ELP from the viewpoint of constituting a planar-type display device.

Furthermore, the light emitting element PX may employ a configuration including a resonator structure that resonates light. The light emitting element PX has the resonator structure, so that it is possible to set the light emission color of the light emitting element PX to a predetermined display color, and, consequently, a color filter is basically unnecessary. However, the display device 1 may be configured to further include the color filter associated with the light emitting element PX for displaying red to further improve the color purity of light having a long wavelength. Alternatively, the display device 1 may be configured to further include the color filters associated with the light emitting element PX for displaying red, the light emitting element PX for displaying green, and the light emitting element PX for displaying blue to improve the color purity of the overall display colors.

Furthermore, as a constituent material of a substrate 20, a semiconductor material, a glass material, a plastic material, or the like can be used. In a case where a transistor formed on a semiconductor substrate constitutes a drive circuit, there can be employed a configuration where, for example, a well region is provided on the semiconductor substrate made of silicon, and the transistor is formed in a well. On the other hand, in a case where a thin film transistor or the like constitutes the drive circuit, it is possible to use a substrate made of a glass material or a plastic material, form a semiconductor thin film on this substrate, and form the drive circuit. Various wirings can have known configurations and structures.

Furthermore, in the display device 1, a component such as the drive circuit or the like that controls light emission of the light emitting element PX is not particularly limited. The configuration of the transistor that constitutes the drive circuit is not particularly limited, and may be, for example, a p-channel type field effect transistor or may be an n-channel type field effect transistor.

Furthermore, in the display device 1, the light emitting element PX is a so-called top emission type component. For example, the light emitting element PX including an organic electroluminescence element is formed by sandwiching an organic layer including a hole transport layer, a light emission layer, an electron transport layer, and the like between a first electrode and a second electrode. When a cathode is commonalized, the first electrode is an anode electrode, and the second electrode is a cathode electrode. The first electrode is provided per light emitting element PX on the substrate 20.

The first electrode may be formed of, for example, a simple substance or an alloy of metals such as platinum (Pt), gold (Au), silver (Ag), chromium (Cr), tungsten (W), nickel (Ni), copper (Cu), iron (Fe), cobalt (Co), and tantalum (Ta) having a high work function. Furthermore, the first electrode may be formed as a laminated electrode formed by laminating a transparent conductive material such as Indium Zinc Oxide (IZO) or Indium Tin Oxide (ITO) on a dielectric multilayer film or a thin film having high light reflectivity such as aluminum.

The second electrode may be formed of, for example, a metal or an alloy such as aluminum (Al), silver (Ag), magnesium (Mg), calcium (Ca), sodium (Na), strontium (Sr), an alloy of an alkali metal and silver, an alloy of an alkaline earth metal and silver, an alloy of magnesium and calcium, or an alloy of aluminum and lithium having a low work function. Furthermore, the second electrode may be formed of a transparent conductive material such as Indium Zinc Oxide (IZO) or Indium Tin Oxide (ITO), or may be formed as a laminated electrode of a layer that is made of a material having the above-described low work function, and a layer made of a transparent conductive material such as Indium Zinc Oxide (IZO) or Indium Tin Oxide (ITO).

Furthermore, an organic layer 40 is formed by laminating a plurality of material layers, and is provided on the entire surface including the first electrode as a common continuous film. The organic layer 40 emits light when a voltage is applied between the first electrode and the second electrode. The organic layer 40 has, for example, a structure formed by laminating from the first electrode side a hole injection layer, a hole transport layer, a light emission layer, an electron transport layer, and an electron injection layer in order. The hole transport material, the hole transport material, the electron transport material, and the organic light emission material constituting the organic layer 40 are not limited, and known materials can be used.

Furthermore, the organic layer 40 may have a structure formed by laminating a plurality of light emission layers. By, for example, laminating light emission layers for red light emission, blue light emission, and green light emission, or by laminating light emission layers for blue light emission and yellow light emission, the light emitting element PX that emits white light can be formed. Furthermore, the light emission layer can be also colored differently and formed per light emitting element PX according to the color to be displayed.

Furthermore, the pixel may include the one light emitting element PX, or may include the plurality of light emitting elements PX. For example, the pixel may include a plurality of subpixels (light emitting elements PX). More specifically, one pixel can use a configuration including three types of subpixels of a red display subpixel, a green display subpixel, and a blue display subpixel. Furthermore, one pixel can use one set to which one type or a plurality of types of subpixels has been added in addition to the three types of subpixels (e.g., one set to which a subpixel that emits white light to improve luminance has been added, one set to which a subpixel that emits light of a complementary color has been added to expand a color reproduction range, one set to which a subpixel that emits yellow light has been added to expand a color reproduction range, and one set to which subpixels that emit yellow light and cyan light have been added to expand a color reproduction range).

Furthermore, a partition wall part that defines the adjacent light emitting elements PX may be formed using a material appropriately selected from known inorganic materials and organic materials. For example, the partition wall part may be formed by a combination of a known film forming method such as a Physical Vapor Deposition method (PVD method) exemplified by a vacuum vapor deposition method and a sputtering method or various Chemical Vapor Deposition methods (CVD methods), and a known patterning method such as an etching method or a lift-off method.

Furthermore, a value of a pixel (pixel) of the display device 1 can be exemplified as some image display resolutions such as VGA (640, 480), S-VGA (800, 600), XGA (1024, 768), APRC (1152, 900), S-XGA (1280, 1024), U-XGA (1600, 1200), HD-TV (1920, 1080), and Q-XGA (2048, 1536), and, in addition, (1920, 1035), (720, 480), and (1280, 960), yet is not limited to these values.

### 4. Application Example

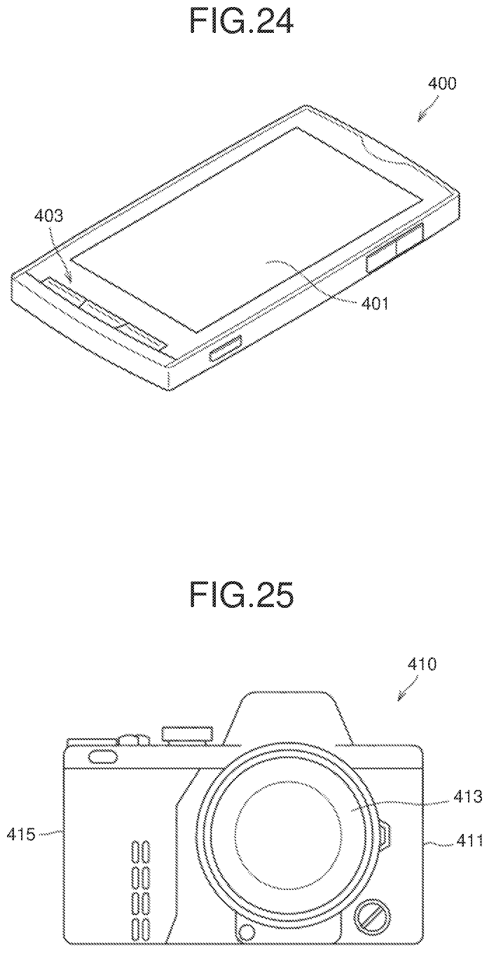

The application example of the display device 1 according to each embodiment will be described with reference to FIGS. 24 to 27. FIGS. 24 to 27 are views each illustrating an example of an electronic device including the display device 1 according to each embodiment.

For example, the display device 1 according to each embodiment is applied to a display unit included in the electronic device. Examples of the electronic device include a smartphone, a digital camera, a Head Mounted Display (HMD), a video camera, a tablet terminal, a mobile phone, a Personal Digital Assistant (PDA), a notebook Personal Computer (PC), an electronic book, a game device, a television device, and the like.

For example, the display device 1 according to each embodiment is applied to a display unit of a smartphone. More specifically, as illustrated in FIG. 24, a smartphone 400 includes a display unit 401 that displays various pieces of information, and an operation unit 403 that includes a button or the like that accepts an operation input by a user. Here, the display unit 401 is configured as the display device 1 according to the present embodiment.

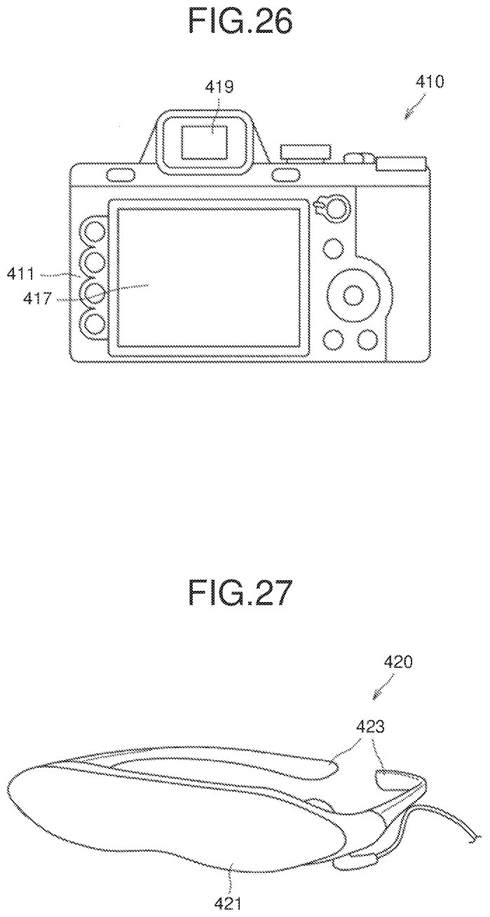

Furthermore, for example, the display device 1 according to each embodiment is applied to a display unit of a digital camera. More specifically, as illustrated in FIGS. 25 and 26, a digital camera 410 includes a main body part (camera body) 411, an interchangeable lens unit 413, a grip part 415 that is gripped by the user at a time of photographing, a monitor unit 417 that displays various pieces of information, and an Electronic View Finder (EVF) 419 that displays a through image observed by the user at the time of photographing. Note that FIG. 25 illustrates an external appearance of the digital camera 410 seen from the front (i.e., subject side), and FIG. 26 illustrates an external appearance of the digital camera 410 seen from the back (i.e., photographer side). Here, the monitor unit 417 and the EVF 419 are configured as the display device 1 according to the present embodiment.

Furthermore, for example, the display device 1 according to each embodiment is applied to a display unit of an HMD. More specifically, as illustrated in FIG. 27, an HMD 420 includes an eyeglass-type display unit 421 that displays various pieces of information, and ear hook parts 423 that are hooked to the user's ears when attached. Here, the display unit 421 is configured as the display device 1 according to the present embodiment.

Note that the electronic device to which the display device 1 according to each embodiment can be applied is not limited to the above examples. The display device 1 according to each embodiment can be applied to a display unit of an electronic device in any field that performs display based on an image signal input from an outside or an image signal generated inside. That is, the technique according to the present disclosure can be applied to various products. For example, the display device 1 according to each embodiment may be implemented as a display unit of any type of mobile bodies such as automobiles, electric vehicles, hybrid electric vehicles, motorcycles, bicycles, personal mobilities, airplanes, drones, ships, robots, construction machines, and agricultural machines (tractors). Furthermore, for example, the display device 1 according to each embodiment may be applied to a display unit included in an endoscopic surgery system, a microscopic surgery system, or the like.

Although the embodiments, the modified examples, and the application example of the present disclosure have been described in detail with reference to the accompanying drawings, the technical scope of the present disclosure is not limited to these embodiments. It is obvious that a person having common knowledge in the technical field of the present disclosure can arrive at various modified examples or altered examples within the scope of the technical idea recited in the claims, and it is naturally understood that these modified examples or altered examples also belong to the technical scope of the present disclosure.

### 5. Supplementary Note

Note that the technique according to the present disclosure can also employ the following configurations.

(1)

A light emitting element comprising:
a light emitting unit;
an intermediate layer that is provided on the light emitting unit; and
a color filter layer that is provided on the intermediate layer,
wherein the color filter layer includes a protrusion part that protrudes towards the intermediate layer.

(2)

The light emitting element according to (1), wherein
the protrusion part is provided in a groove formed in the intermediate layer.

(3)

The light emitting element according to (1) or (2), wherein
the protrusion part is formed in a ring shape in plan view.

(4)

The light emitting element according to any one of (1) to (3), wherein
the light emitting unit includes a first electrode, and
the protrusion part is formed in a same shape as an outer shape of the first electrode in plan view.

(5)

The light emitting element according to any one of (1) to (4), wherein
the light emitting unit includes a first electrode, and
the protrusion part is formed so as to be located on an outer side of an outer shape of the first electrode in plan view.

(6)

The light emitting element according to any one of (1) to (5), wherein
the protrusion part is a color filter that has a same color as a color of the color filter layer.

(7)

The light emitting element according to any one of (1) to (5), wherein
the protrusion part is a color filter that has a different color from a color of the color filter layer.

(8)

The light emitting element according to any one of (1) to (7), wherein
a length in a depth direction or a width in a planar direction of the protrusion part is set according to a desired chromaticity viewing angle.

(9)

The light emitting element according to any one of (1) to (8), wherein
a shape of the protrusion part is set according to a desired chromaticity viewing angle.

(10)

The light emitting element according to any one of (1) to (9), wherein
the color filter layer is shifted in a planar direction with respect to the light emitting unit.

(11)

The light emitting element according to (1), wherein
the color filter layer includes a plurality of the protrusion parts.

(12)

The light emitting element according to (11), wherein
the plurality of protrusion parts are each formed in a rectangular shape or a ring shape in plan view.

(13)

The light emitting element according to (11) or (12), wherein
individual lengths in a depth direction or individual widths in a planar direction of the plurality of protrusion parts are different from each other.

(14)

The light emitting element according to any one of (11) to (13), wherein
individual shapes of the plurality of protrusion parts are different from each other.

(15)

The light emitting element according to any one of (11) to (14), wherein
individual lengths in a depth direction or individual widths in a planar direction of the plurality of protrusion parts are set according to a desired chromaticity viewing angle or a desired luminance viewing angle.

(16)

The light emitting element according to any one of (11) to (15), wherein
individual shapes of the plurality of protrusion parts or a number of the plurality of protrusion parts are set according to a desired chromaticity viewing angle or a desired luminance viewing angle.

(17)

A display device comprising
a plurality of light emitting elements, wherein
the plurality of light emitting elements each include
a light emitting unit,
an intermediate layer that is provided on the light emitting unit, and
a color filter layer that is provided on the intermediate layer, and
the color filter layer includes a protrusion part that protrudes towards the intermediate layer.

(18)

The display device according to (17), wherein
individual lengths in a depth direction or individual widths in a planar direction of the protrusion parts of the plurality of light emitting elements are different from each other.

(19)

The display device according to (17) or (18), wherein
individual shapes of the protrusion parts of the plurality of light emitting elements are different from each other.

(20)

An electronic device comprising
a display device that includes a plurality of light emitting elements, wherein
the plurality of light emitting elements each include
a light emitting unit,
an intermediate layer that is provided on the light emitting unit, and
a color filter layer that is provided on the intermediate layer, and
the color filter layer includes a protrusion part that protrudes towards the intermediate layer.

(21)

A display device including the plurality of light emitting elements according to any one of (1) to (16).

(22)

An electronic device including the display device according to any one of (17) to (19).

(23)

An electronic device including the display device that includes the plurality of light emitting elements according to any one of (1) to (16).

### REFERENCE SIGNS LIST

1 DISPLAY DEVICE
11 HORIZONTAL DRIVE CIRCUIT
12 VERTICAL DRIVE CIRCUIT
20 SUBSTRATE
30 ANODE LAYER
31 ANODE ELECTRODE
32 INSULATION LAYER
40 ORGANIC LAYER
50 CATHODE LAYER
60 PROTECTION LAYER
70 COLOR FILTER LAYER
70R COLOR FILTER
70B COLOR FILTER
70G COLOR FILTER
71 PROTRUSION PART
80 PLANARIZATION LAYER
90 RESIST LAYER
100 BARRIER
400 SMARTPHONE
401 DISPLAY UNIT
403 OPERATION UNIT
410 DIGITAL CAMERA
411 MAIN BODY PART
413 LENS UNIT
415 GRIP PART
417 MONITOR UNIT
420 HMD
421 DISPLAY UNIT
423 EAR HOOK PART
A1 DRIVE CIRCUIT
DTL SIGNAL LINE
ELP LIGHT EMITTING UNIT
M1 GROOVE
PS1 FEEDER LINE
PS2 COMMON FEEDER LINE
PX LIGHT EMITTING ELEMENT
SCL SCAN LINE
TR_{D} DRIVE TRANSISTOR
TR_{W} WRITE TRANSISTOR

1. A light emitting element comprising:
a light emitting unit;
an intermediate layer that is provided on the light emitting unit; and
a color filter layer that is provided on the intermediate layer,
wherein the color filter layer includes a protrusion part that protrudes towards the intermediate layer.

2. The light emitting element according to claim 1, wherein
the protrusion part is provided in a groove formed in the intermediate layer.

3. The light emitting element according to claim 1, wherein
the protrusion part is formed in a ring shape in plan view.

4. The light emitting element according to claim 1, wherein
the light emitting unit includes a first electrode, and
the protrusion part is formed in a same shape as an outer shape of the first electrode in plan view.

5. The light emitting element according to claim 1, wherein
the light emitting unit includes a first electrode, and
the protrusion part is formed so as to be located on an outer side of an outer shape of the first electrode in plan view.

6. The light emitting element according to claim 1, wherein
the protrusion part is a color filter that has a same color as a color of the color filter layer.

7. The light emitting element according to claim 1, wherein
the protrusion part is a color filter that has a different color from a color of the color filter layer.

8. The light emitting element according to claim 1, wherein
a length in a depth direction or a width in a planar direction of the protrusion part is set according to a desired chromaticity viewing angle.

9. The light emitting element according to claim 1, wherein
a shape of the protrusion part is set according to a desired chromaticity viewing angle.

10. The light emitting element according to claim 1, wherein
the color filter layer is shifted in a planar direction with respect to the light emitting unit.

11. The light emitting element according to claim 1, wherein
the color filter layer includes a plurality of the protrusion parts.

12. The light emitting element according to claim 11, wherein
the plurality of protrusion parts are each formed in a rectangular shape or a ring shape in plan view.

13. The light emitting element according to claim 11, wherein
individual lengths in a depth direction or individual widths in a planar direction of the plurality of protrusion parts are different from each other.

14. The light emitting element according to claim 11, wherein
individual shapes of the plurality of protrusion parts are different from each other.

15. The light emitting element according to claim 11, wherein
individual lengths in a depth direction or individual widths in a planar direction of the plurality of protrusion parts are set according to a desired chromaticity viewing angle or a desired luminance viewing angle.

16. The light emitting element according to claim 11, wherein
individual shapes of the plurality of protrusion parts or a number of the plurality of protrusion parts are set according to a desired chromaticity viewing angle or a desired luminance viewing angle.

17. A display device comprising
a plurality of light emitting elements, wherein
the plurality of light emitting elements each include
a light emitting unit,
an intermediate layer that is provided on the light emitting unit, and
a color filter layer that is provided on the intermediate layer, and
the color filter layer includes a protrusion part that protrudes towards the intermediate layer.

18. The display device according to claim 17, wherein
individual lengths in a depth direction or individual widths in a planar direction of the protrusion parts of the plurality of light emitting elements are different from each other.

19. The display device according to claim 17, wherein
individual shapes of the protrusion parts of the plurality of light emitting elements are different from each other.

20. An electronic device comprising
a display device that includes a plurality of light emitting elements, wherein
the plurality of light emitting elements each include
a light emitting unit,
an intermediate layer that is provided on the light emitting unit, and
a color filter layer that is provided on the intermediate layer, and
the color filter layer includes a protrusion part that protrudes towards the intermediate layer.
